(19) United States
(12) Patent Application Publication
(10) Pub. No.: US 2023/0246004 A1
(43) Pub. Date: Aug. 3, 2023

(54) Enhanced Colour Conversion and Collimation of Micro-LED Devices

(71) Applicant: Plessey Semiconductors Limited, Plymouth (GB)

(72) Inventor: Samir MEZOUARI, Plymouth (GB)

(73) Assignee: Plessey Semiconductors Limited, Plymouth (GB)

(21) Appl. No.: 18/008,066

(22) PCT Filed: May 28, 2021
(86) PCT No.: PCT/EP2021/064359

§ 371 Date: Dec. 2, 2022

(30) Foreign Application Priority Data
Jun. 4, 2020 (GB) 2008437.2

(51) Int. Cl. H01L 25/075; H01L 33/50; H01L 33/60

(52) U.S. Cl. CPC H01L 25/0753; H01L 33/502; H01L 33/60

(57) ABSTRACT

A pixel comprising a first sub-pixel. The first sub-pixel comprises an LED layer comprising a light-emitting material configured to emit pump light having a pump wavelength. A container layer has a container surface comprising a first container aperture that defines a first container volume extending through the container layer. A first colour converting layer provided in the first container volume is configured to receive pump light from the LED layer and emit first converted light of a first converted wavelength. A first lens is provided on the container layer over the first container aperture, having an outer side that comprises a first convex surface. A first reflector conforming to the first convex surface comprises a first reflector configured to reflect light at the pump wavelength and transmit light at the first converted wavelength; and a second reflector configured to reflect light at both the pump wavelength and the first converted wavelength.

### FIELD OF THE DISCLOSURE

The disclosure relates to the field of Light Emitting Diodes (LEDs) and LED arrays.

### BACKGROUND

Micro-LED arrays are commonly defined as arrays of LEDs with a size of 100×100 μm² or less. Micro-LED arrays are a self-emitting micro-display or projector which are suitable for use in a variety of devices such as smart watches, head-wearing displays, head-up displays, camcorders, viewfinders, multisite excitation sources and pico-projectors.

In many applications, it is useful to provide a colour display or projector by using a micro-LED array that is capable of emitting light having a range of wavelengths. For example, a colour display may comprise a micro-LED array having a plurality of pixels on a common substrate, wherein each pixel may output a combination of different colours of light. For example, a pixel may output a combination of red, green and blue light. This is generally achieved by one of two approaches, both making use of a pixel comprising a plurality of sub-pixels which each emit light of a different colour. In one approach each sub-pixel may comprise a micro-LED configured to emit light of a different wavelength. In another approach, the micro-LEDs in each sub-pixel may emit light of the same wavelength and may be provided with a colour converting material. The colour converting material may convert light of a higher energy (pump light) into light of a lower energy (converted light), changing the colour of the light emitted by sub-pixel. Examples of colour converting materials are phosphors and quantum dots.

A challenge associated with using colour converting material is to efficiently convert light from the pump wavelength to the converted light wavelength. For example, the colour converting material may absorb some converted light, reducing efficiency. Another challenge is to extract only the converted light from the device since the colour converting material may be too thin to convert all of the pump light to converted light. If any pump light leaks from the micro-LED, the colour purity of the micro-LED is reduced.

To achieve good colour saturation by reducing pump light leakage, common methods use optical filters to either reflect the pump light back to the micro-LED to recycle it or use a high band pass optical filter to absorb the pump light. One example of such an optical filter is a distributed Bragg Reflector that reflects the pump light and transmits the converted light. In “Optical cross-talk reduction in a quantum dot-based full-colour micro-light-emitting-diode display by a lithographic-fabricated photoresist mold”, Photonics 25 Research, Vol. 5, No. 5, October 2017, a UV micro-LED array is used as an efficient excitation source for Quantum Dots (QD). To reduce optical cross-talk between sub-pixels, a simple lithography method and photoresist are used to fabricate a mould, which consists of an opening for the addition of QDs and a blocking wall for cross-talk reduction. A Distributed Bragg Reflector (DBR) is provided over the QDs to reflect the UV light passing through the QDs, thereby increasing the light emission of the QDs. The DBR also acts to increase the colour purity of the LED by preventing pump light from passing through the LED.

To further reduce the pump light leakage, the portion of the LED in which the colour converting material is provided may be lined with a material configured to absorb pumplight. In “Monolithic Red/Green/Blue Micro-LEDs with HBR and DBR structures” Guan-Syun Chen, et. al, IEEE Photonics Technology Letters, Vol. 30, No. 3, 1 Feb. 2018, a black matrix photoresist with light blocking capability is spun onto micro-LEDs. The black matrix photoresist can block blue light emitted from the side of a blue micro-LED including red or green quantum dots. Thus, blue light cross talk between adjacent LEDs is reduced by the black matrix photoresist. However, the conversion efficiency is considerably reduced because all visible light that is incident on the inside-walls of each sub-pixel is absorbed.

Additional colour filters may also be used, wherein colourants are mixed with colour resists and used as filters for micro-LEDs. The choice of dye may contribute to the brightness of the colour filters (“Development of Color Resists Containing Novel Dyes for Liquid Crystal Displays”, Sumitomo Kagaku, vol. 2013).

A further challenge associated with the use of micro-LEDs is improving the coupling efficiency of a micro-LED emissive display to a projection or relay lens. Only light that it is within the acceptance angle of the lens can be used, and the remaining light is lost. Micro-LEDs typically emit light in an angular distribution close to a Lambertian emission with a full-width half maximum (FWHM) of 120 degrees. The acceptance angle of a lens is determined by its F number, which for a typical projection lens might be F/2.5 or F/3 giving acceptance angles 11.3° and 9.5° respectively. Only 2.7% of light emitted by a Lambertian micro-LED is within ±9.5°, so 97.3% of light is lost as stray light and the efficiency of collecting the light is very low.

An approach used to enhance emission efficiency is to introduce random nanotexturing on the LED surface, with features on the scale of the wavelength of light leading to chaotic behaviour of light and increased emission efficiency (Applied Physics Letters 63, 1993, pp. 2174-2176). Similarly, periodic or non-periodic patterns on the order of the light wavelength can be introduced to the emitting surface or internal interfaces of LEDs, with interference effects increasing light extraction (U.S. Pat. Nos. 5,779,924 A and 6,831,302 B1). However, roughening results in multiple internal reflections before the light escapes which results in losses.

Achieving collimation usually relies on secondary optical elements, often consisting of a micro-lens array where each micro-lens is aligned with the individual micro-LED to collimate the emitted light (e.g. US2009115970, US2007146655 and US2009050905 A1). These must be precisely aligned with the LED array.

Shaping the sidewalls of LEDs can improve manufacturing and increased light extraction (e.g. U.S. Pat. No. 7,598,149 B2). Etching of the mesa, to form a parabolic mesa structure in which the active layer sits, can also collimate the light emitted (US2015236201 A1 and US2017271557 A1). Light is reflected from the internal surface of the mesa and out of the LED from an emission surface opposed to the mesa. This method risks damaging the active layer, and it is hard to achieve a smooth finish when etching the mesa so there is roughness on the mesa side of the active layer which decreases the degree of collimation that is possible.

There is a need to collimate the light emitted by micro-LEDs such that the FWHM is reduced and the light collection efficiency is increased. There is also a need to further improve the colour purity and also the efficiency of micro-LEDs comprising colour converting materials.

### SUMMARY OF THE DISCLOSURE

Against this background, there is provided:

A pixel comprising a first sub-pixel, wherein the first sub-pixel comprises:
an LED layer comprising a light-emitting material configured to emit pump light from a light-emitting surface, the pump light having a pump wavelength;
a container layer having a container surface comprising a first container aperture that defines a first container volume extending through the container layer;
a first colour converting layer provided in the first container volume and configured to receive light from the light-emitting surface of the LED layer, wherein the first colour converting layer comprises a first colour converting material that is configured to absorb light at the pump wavelength and emit first converted light of a first converted wavelength;
a first lens provided on the container layer over the first container aperture, comprising an inner side adjacent to the colour converting layer and an outer side, wherein the outer side comprises a first convex surface;
a first reflector assembly adjacent the outer side of the first lens and conforming to the first convex surface, the first reflector assembly comprising:
   a first reflector configured to reflect light at the pump wavelength and transmit light at the first converted wavelength; and
   a second reflector configured to reflect light at both the pump wavelength and the first converted wavelength;
wherein the second reflector comprises a first sub-pixel reflector aperture and wherein the first reflector fills the first sub-pixel reflector aperture.

In this way, it is possible to increase the colour saturation of the sub-pixel by reflecting any pump light that is not converted by the colour converting material such that it enters the colour converting material and has another chance to be converted. Light at the pump wavelength may pass through the colour converting material as many times as it takes for the light to be converted to light at the converted wavelength. It is also possible to increase the optical efficiency of the sub-pixel, since light may only be emitted through the reflector aperture. In this way the emitted light beam is collimated, increasing the proportion of the emitted light that can be captured by a light collection device since the proportion of the emitted light beam that is within the collection angle of the light collection device is increased.

The pixel may further comprise a second sub-pixel, wherein the second sub-pixel comprises:
an LED layer comprising a light-emitting material configured to emit pump light from a light-emitting surface, the pump light having the pump wavelength;
a container layer having a container surface comprising a second container aperture that defines a second container volume extending through the container layer;
a second colour converting layer provided in the second container volume and configured to receive light from the light-emitting surface of the LED layer, wherein the second colour converting layer comprises a second colour converting material that is configured to absorb light at the pump wavelength and emit second converted light of a second converted wavelength;
a second lens provided on the container layer over the second container aperture, comprising an inner side adjacent to the colour converting layer and an outer side, wherein the outer side comprises a second convex surface;
a second reflector assembly adjacent the outer side of the second lens and conforming to the second convex surface, the second reflector assembly comprising:
   a third reflector configured to reflect light at the pump wavelength and transmit light at the second converted wavelength; and
   a fourth reflector configured to reflect light at both the pump wavelength and the second converted wavelength;
wherein the fourth reflector comprises a second sub-pixel reflector aperture and wherein the third reflector fills the second sub-pixel reflector aperture.

Advantageously, a pixel may comprise a plurality of sub-pixels with different colour converting materials such that the pixel comprises sub-pixels of different colours that have the increased colour saturation and optical efficiency of the sub-pixel of this disclosure.

The pixel may further comprise a third sub-pixel that emits light at the pump wavelength, wherein the third sub-pixel comprises:
an LED layer comprising a light-emitting material configured to emit pump light from a light-emitting surface, the pump light having the pump wavelength;
a container layer having a container surface comprising a third container aperture that defines a third container volume through the container layer;
a lens provided on the container layer over the third container aperture, comprising an inner side adjacent to the container layer and an outer side, wherein the outer side comprises a third convex surface;
a third reflector assembly adjacent to the outer side of the third lens and conforming to the third convex surface, the third reflector assembly comprising:
   a fifth reflector configured to reflect pump light, wherein the fifth reflector comprises a third sub-pixel reflector aperture.

In this way, the pixel may include a sub-pixel that is the colour of the pump light and that still has the increased optical efficiency of the sub-pixel of this disclosure.

The central axis of the first reflector and a central axis of the second reflector are aligned with a central axis of the convex surface.

Advantageously, the collimated light beam therefore has a central axis that is parallel to the normal of the container layer.

The first reflector may comprise a laminate structure.

The first reflector may comprise alternating layers of higher and lower refractive index.

In this way the reflectance of the first reflector to light at the first converted wavelength may be decreased.

The first reflector may comprise a plurality of layers of TiO₂ and SiO₂.

Advantageously, a first reflector with this structure may have a reflectance light at the first converted wavelength of less than 5%.

The first reflector may comprise a distributed Bragg reflector.

In this way, the first reflector may transmit light at the converted wavelength and reflect light at the pump wavelength.

The second reflector may comprise a metallic material.

In this way, the second reflector may reflect light at all visible wavelengths, such that it reflects light at both pump and first converted wavelengths.

The container volume may comprise reflective inner sidewalls.

Advantageously, this may increase the light extraction efficiency of the sub-pixel by increasing the proportion of light that is emitted by the light-emitting surface of the LED layer that exits the container volume via the container aperture.

The area of the container aperture may be at least equal to the area of the light-emitting surface of the LED layer.

An inner sidewall of the container volume may form an angle relative to the normal to the light-emitting surface of the LED layer of at least 35° and no greater than 85°, or preferably no greater than 60°.

Advantageously, this may increase the light extraction efficiency of the sub-pixel by increasing the proportion of light incident on the inner sidewall that is reflected towards the container aperture. In this way the proportion of light that is emitted by the light-emitting surface of the LED layer that exits the container volume via the container aperture is increased.

The container aperture may be circular such that the container volume resembles a truncated inverted cone, or the container aperture may be rectangular such that the container volume resembles a truncated inverted square pyramid.

In this way, the container volume may be designed to increase optical efficiency by having sloped inner sidewalls and having a cross section in the plane of the container layer that might be, for example, the same shape as the light-emitting surface of the LED layer.

The lens may be hemispherical.

Advantageously, light that is reflected at the convex surface by one of the reflectors may be reflected along a path that is the same or similar to the incident path, such that the proportion of reflected light that is incident on the colour converting material is increased. In this way, the proportion of reflected light at the pump wavelength that is subsequently converted to light at the converted wavelength is increased.

The convex surface of the lens may be elliptical or parabolic.

In this way light that is reflected by one of the reflectors may be subsequently reflected again from one of the reflectors such that it is incident on the colour converting material.

A characteristic dimension of the lens may be at least twice as large as a characteristic dimension of the aperture in the plane of the container layer.

Advantageously, the angle of incidence of the light emitted from the edge of the container aperture on the convex surface may be reduced, such that if the light is reflected its reflected path is similar to its incident path and the proportion of reflected light that is incident on the colour converting material is increased.

The pixel may further comprise a converted light reflector laminate at an interface between the LED layer and the colour converting layer.

In this way the optical efficiency of the sub-pixel is increased by increasing the proportion of light in the container volume that is reflected towards the container aperture.

The full-width half-maximum of the light at the converted wavelength that is transmitted through the first reflector may be less than 60°, or preferably less than 50°.

In this way the coupling efficiency of the sub-pixel to a light collection device is increased by collimating the emitted light beam such that the proportion of the emitted light beam that is within the collection angle of the light collection device is increased.

The reflectance of the first reflector to light at the pump wavelength may be more than 95%, or preferably 100%.

Advantageously, this increases the colour saturation of the sub-pixel by reducing the amount of light at the pump wavelength that is emitted from the sub-pixel.

The reflectance of the first reflector to light at the converted wavelength may be less than 10%, or preferably less than 5%.

Advantageously, this increases the optical efficiency of the sub-pixel by increasing the proportion of light at the converted wavelength incident on the first reflector that is transmitted by the first reflector.

The converted wavelength may be longer than the pump wavelength.

The colour converting layer may comprise a quantum dot material.

The pump wavelength may be blue and the first converted wavelength may be a first one of a colour group comprising red and green.

The second converted wavelength may be a second one of the colour group.

The container volume of the third sub-pixel may be filled with a translucent material.

In this way the pixel may comprise an RGB (red, green, blue) triplet.

### BRIEF DESCRIPTION OF THE DRAWINGS

A specific embodiment of the disclosure will now be described, by way of example only, with reference to the accompanying drawings in which:

FIG. 1 shows a common sub-pixel arrangement.

FIG. 2 shows a schematic cross section of a sub-pixel in accordance with the disclosure. FIG. 2A shows the container volume and pump light LED of the sub-pixel, FIG. 2B shows the placement of the lens over the container aperture of the sub-pixel, and FIG. 2C shows the complete sub-pixel comprising a colour converting material and reflectors provided on the lens.

FIG. 3 shows a schematic cross section of a pixel in accordance with the disclosure.

FIG. 3A shows the container volumes and pump light LEDs of the pixel, and FIG. 3B shows the complete pixel.

FIG. 4 illustrates the refraction of light rays when they exit the lens.

FIG. 5 illustrates the paths of pump light and converted light for a pixel comprising lenses on each sub-pixel but no reflectors.

FIG. 6 illustrates the emission spectra for the sub-pixels of FIG. 5, wherein the pump light LEDs are blue. FIG. 6A corresponds to a sub-pixel comprising a colour converting material that converts blue light to red light, FIG. 6B corresponds to a sub-pixel comprising a colour converting material that converts blue light to green light, and FIG. 6C corresponds to a sub-pixel without colour converting material.

FIG. 7 shows the emission distribution for a sub-pixel of FIG. 5.

FIG. 8 illustrates the paths of pump light and converted light for a pixel in accordance with the disclosure, comprising hemispherical lenses and reflectors on each sub-pixel.

FIG. 9 illustrates the emission spectra for the sub-pixels of FIG. 8, wherein the pump light LEDs are blue. FIG. 9A corresponds to a sub-pixel comprising a colour converting material that converts blue light to red light, FIG. 9B corresponds to a sub-pixel comprising a colour converting material that converts blue light to green light, and FIG. 9C corresponds to a sub-pixel without colour converting material.

FIG. 10 shows the emission distribution for a sub-pixel of FIG. 8.

FIG. 11 illustrates the paths of pump light and converted light for a pixel in accordance with the disclosure, comprising parabolic or elliptical lenses and reflectors on each sub-pixel.

FIG. 12 shows the reflectance of a laminate reflector in accordance with the disclosure.

FIG. 13 shows a schematic of the structure of a laminate reflector in accordance with the disclosure.

FIG. 14 shows the reflectance of a distributed Bragg reflector.

FIG. 15 shows a schematic cross section of a sub-pixel in accordance with the disclosure, in which the container volume comprises sloped inner sidewalls.

FIG. 16 shows a schematic plan view of a plurality of sub-pixels in accordance with the disclosure.

FIG. 17 illustrates some of the steps of fabrication of a pixel in accordance with the embodiment. FIG. 17A shows the deposited container layer, FIG. 17B shows the patterned container layer, FIG. 17C shows the container volumes filled with colour converting or transparent materials, and FIG. 17D shows the lenses over the container apertures.

FIG. 18 illustrates examples of the structure of the reflectors. FIG. 18A shows the second reflector comprising the reflector aperture deposited on the lens first, then the first reflector is deposited and coats the whole convex surface. FIG. 18b shows the first reflector deposited on the lens first, coating the whole convex surface, and then the second reflector comprising the reflector aperture is deposited. FIG. 18C illustrates an example wherein the first reflector is provided only in the reflector aperture of the second reflector, with small overlap between the reflectors.

### DETAILED DESCRIPTION

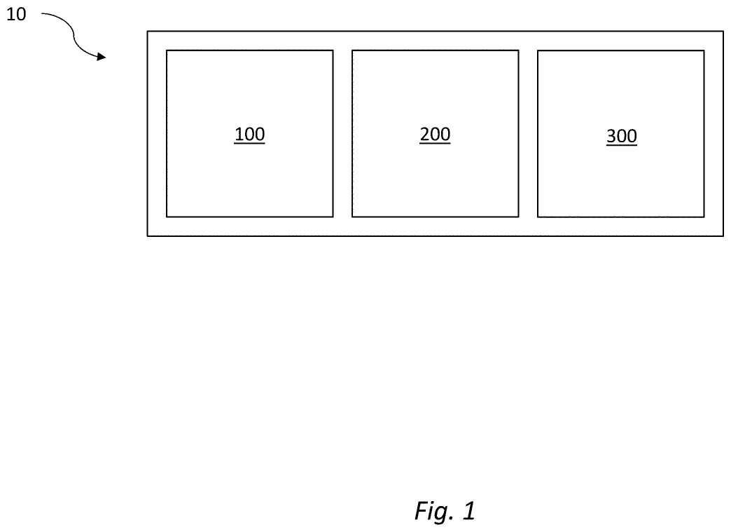

A common sub-pixel configuration for a pixel 10 is indicated in FIG. 1. The pixel 10 may comprise first, second and third sub-pixels 100, 200 and 300, wherein the first, second and third sub-pixels may emit light of different wavelengths. For example, the first sub-pixel 100 may be red, the second sub-pixel 200 may be green and the third sub-pixel 300 may be blue. According to an embodiment of the disclosure, a pixel 10 may be provided wherein each sub-pixel comprises a light-emitting diode and wherein at least one light-emitting diode includes a colour converting material. As such, the pixel 10 also includes a light-emitting diode according to an embodiment of this disclosure.

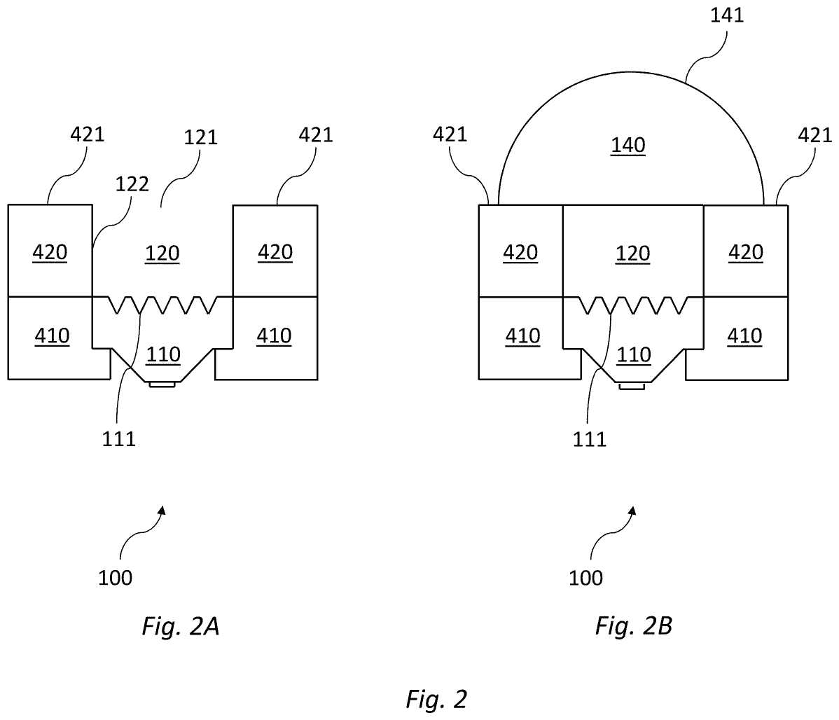

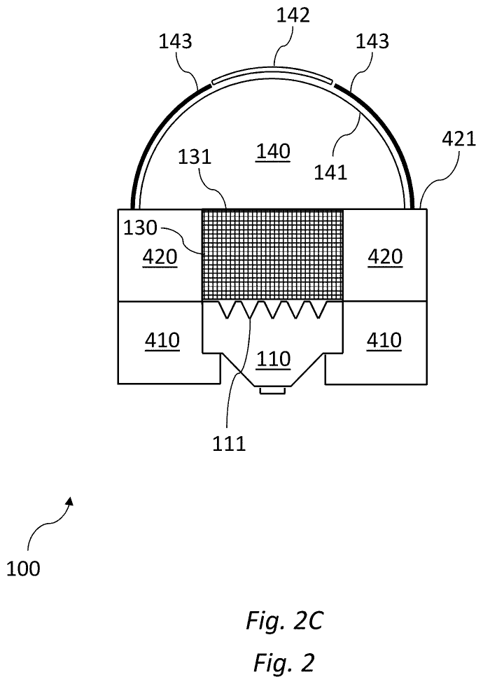

A light-emitting diode in accordance with an embodiment of the disclosure is illustrated as a first sub-pixel 100 in FIG. 2C. FIGS. 2A and 2B show parts of the sub-pixel 100 to help clarify the description. With reference to FIG. 2A, the sub-pixel 100 may comprise a light generating layer comprising a semiconductor junction configured to output pump light, such that the light-generating layer may be considered to comprise a pump light LED 110. The pump light LED 110 may comprise a semiconductor material with a first doped region and a second doped region (not shown). The interface (not shown) between the first doped region and the second doped region may comprise a plurality of quantum wells and may be configured to generate light when an electrical current is applied. The pump light LED 110 may comprise Group III-nitrides. The light generating layer may be fabricated on a substrate, and the side of the pump light LED 110 that is opposite to the substrate may comprise the light-emitting surface 111 of the pump light LED 110.

The pump light LED 110 is configured to generate light having a pump light wavelength. In an example, the wavelength of the pump light may correspond to blue visible light. In some embodiments, the wavelength of the pump light may be at least 440 nm and/or no greater than 470 nm. In particular, the wavelength of the pump light may be at least 450 nm and/or no greater than 460 nm. In this disclosure, where a LED is described as emitting light having a wavelength, said wavelength is considered to be the wavelength of light emitted by the LED having the highest intensity (peak intensity). The wavelength of the pump light may be determined by the quantum wells present at the interface between the first doped region and the second doped region.

The pump light LED 110 is contained within a base layer 410. The base layer 410 may comprise a light blocking material. The sub-pixel 100 comprises a container layer 420 provided on the base layer 410. In an embodiment, the container layer 420 may be made from metal. For example, the container layer 420 may be fabricated from Aluminium. The side of the container layer 420 opposite to the side of the container layer 420 adjacent to the base layer 410 defines a container surface 421 comprising a container aperture 121. The container aperture 121 defines a container volume 120 through the container layer 420 to the light-emitting surface 111 of the pump light LED 110. The inner sidewalls 122 of the container volume may surround the light-emitting surface 111 of pump light LED 110, such that the container volume 120 is generally aligned with the pump light LED 110. A side of the container volume 120 that is opposite to the container aperture 121 may comprise the light-emitting surface 111 of the pump light LED 110. In an embodiment in which the container layer 420 is made from metal, the inner sidewalls 122 are reflective such that light emitted by the light-emitting surface 111 of the pump light LED 110 that is incident on the inner sidewalls 122 may be reflected at least once and subsequently emitted through the container aperture. In an embodiment in which the container layer 420 is not made from metal, the inner sidewalls 122 may be coated in a reflective coating. In an embodiment, there may be a thin layer between the container layer 420 and the wafer containing the base layer 410 and LED 110 for electric isolation. For example, the thin layer may be a dielectric passivation layer with a thickness of approximately 100 nm.

In certain embodiments, the container aperture 121 may have an area that is at least equal to the area of the light-emitting surface 111 of the pump light LED 110. In certain embodiments, a side of the container volume 120 that is adjacent to the light-emitting surface 111 of the pump light LED 110 may have an area that is at least equal to the area of the light-emitting surfaces 111 of the pump light LED 110. A central axis of the container volume 120 may be aligned with a central axis of the pump light LED 110. The area of the container aperture 121 may be at least equal to the area of the side of the container volume 120 that is adjacent to the light-emitting surface 111 of the pump light LED 110.

The container aperture 121 may be provided in a variety of different shapes. For example, the container aperture 121 may be elliptical, rectangular, hexagonal, or any form of regular or irregular polygon. In some embodiments, the shape of the container aperture 121 may correspond to a shape of the light-emitting surface 111 of the pump light LED 110. In some other embodiments, the shape of the container aperture 121 may be different to a shape of the light-emitting surface 111 of the pump light LED 110. Depending on the shape of the container apertures 121, the container volume 120 may comprise one or more inner sidewalls 122. For example, for an elliptical container aperture 121 the container volume 120 may comprise a single continuous inner sidewall 122. For a rectangular container aperture 121 the container volume 120 may comprise four inner sidewalls 122. The number of inner sidewalls 122 may be equal to the number of sides that the shape of the container aperture 121 has.

In certain embodiments, the container aperture 121 may have an area that is at least equal to the area of the light-emitting surface 111 of the pump light LED 110. In certain embodiments, the side of the container volume 120 that is adjacent to the light-emitting surface 111 of the pump light LED 110 may have an area that is at least equal to the area of the light-emitting surface 111 of the pump light LED 110. A central axis of the container volume 120 may be aligned with a central axis of the pump light LED 110. The area of the container aperture 121 may be at least equal to the area of the side of the container volume 120 that is adjacent to the light-emitting surface 111 of the pump light LED 110.

With reference to FIG. 2B, the sub-pixel 100 may further comprise a first lens 140 that is provided on the container surface 421 over the container aperture 121. The first lens 140 may comprise an inner side provided on the container surface 421 and over the container aperture 421, and an outer side that forms a convex surface 141. The first lens 140 is provided in order to reduce the amount of converted light that is totally internally reflected at the interface between the sub-pixel 100 and the outside environment. In a certain embodiment, the convex surface 141 may be hemispherical. Hereafter, the inner side and outer side of the lens 140 may be described as being opposite sides of the lens, even though it is clear that the outer side of the lens 140 joins the inner side of the lens and so the two sides are not always opposite to one another. The outer side of the lens 140 may join the inner side of the lens 140 at an angle of 90° or less.

The container volume 120 of the sub-pixel 100 may be filled with a colour converting layer 130, illustrated in FIG. 2C, that converts light at a pump wavelength to light at a first converted wavelength. In this way, the colour converting layer 130 is configured to convert pump light to first converted light. The light-emitting surface 131 of the colour converting layer may be the side of the colour converting layer that is opposite to the side of the colour converting layer adjacent to the light-emitting surface 111 of the pump light LED 110. The light-emitting surface 131 of the colour converting layer 130 and the container surface 421 may be in the same plane. The pump light LED 110 may emit blue light, as described above. The first colour converting material 130 may convert blue light to red light. The first colour converting material 130 may be configured to convert light having a pump wavelength of at least 440 nm and/or no greater than 480 nm to light having a first converted wavelength of at least 600 nm and/or no greater than 650 nm.

In some embodiments, the colour converting material 130 may comprise quantum dots. In some embodiments, the colour converting material 130 may comprise phosphors. In some embodiments, the colour converting material 130 may comprise organic semiconductors. In some embodiments, the colour converting material 130 may comprise a combination of quantum dots, organic semiconductors and phosphors. For LEDs and LED arrays having container volumes with a surface area in excess of 1 mm², the larger particle size of phosphors may be advantageous. For LEDs and LED arrays having container volumes with surface areas less than 1 mm², for example micro LEDs, it may be advantageous to use a colour converting layer comprising quantum dots or organic semiconductors, due to the smaller particle size. Colour converting materials, including quantum dots are known to the skilled person. Further details of suitable quantum dots for use as a colour converting layer may be found in at least “Monolithic Red/Green/Blue Micro-LEDs with HBR and DBR structures” Guan-Syun Chen, et. al.

The inner sidewalls 122 may be reflective such that a greater proportion of light which is incident on the inner sidewalls 122 will be reflected back into the container volume 120 (relative to light absorbent sidewalls). Thus, a greater proportion of converted light, which may be generated in all directions from the colour converting material 130, may be extracted from the LED. In the event that the container layer 420 is not made from metal, the inner sidewalls 122 may be coated with a reflective material such as a thin film metal, for example Al or Ag.

The sub-pixel 100 may further comprise at least one reflector layer provided on the convex surface 141 of the first lens 140. A first reflector 142 provided on the first lens 140 may be configured to reflect light at the pump wavelength and transmit light at the first converted wavelength. A second reflector 143 may be provided on the first lens 140 that is configured to reflect both light at the pump wavelength and light at the first converted wavelength. The second reflector 143 may comprise a reflector aperture, wherein the first reflector 142 fills the reflector aperture. The first and second reflectors may each conform to portions of the convex surface of the lens of the first sub-pixel. As such, the first and second reflectors 142 and 143 have convex surfaces and so the proportion of converted light that is incident on the first reflector 142 with an angle of incidence greater than 45° is smaller relative to a planar first reflector. The proportion of converted light incident on the first reflector 142 that is totally internally reflected may therefore be reduced. As such, a greater proportion of the converted light that is incident on the first reflector 142 may be transmitted through the first reflector 142, thereby increasing the extraction efficiency of the sub-pixel 100.

Hereafter, light that has a pump wavelength may be referred to as pump light even if it is not emitted directly by the pump light LED 110. For example, light at the pump wavelength that has been reflected by the first reflector 142 and is incident on the colour converting material 130 may be referred to as pump light. Similarly, any light that has the first converted wavelength may be referred to as first converted light even if it is not emitted directly from the colour converting material 130. For example, light at the first converted wavelength that has been reflected from the second reflector 143 may be referred to as first converted light.

The first reflector 142 may be centred on the convex surface 141 of the first lens 140, such that a central axis of the first reflector 142 may be aligned with a central axis of the first lens 140. The centre reflector aperture of the second reflector 143 may also be aligned with the central axis of the first reflector 142 and the central axis of the first lens 140. The entire convex surface 141 of the first lens 140 may be covered by at least one of the first reflector 142 and the second reflector 143.

The lens may comprise an optically transparent material. For example, the lens may comprise silicone, SiO₂, or other dielectric material. The lens can be fabricated using imprint lithography with, for instance a UV-curable hybrid polymers material such as Ormoclear® from “Micro Resist Technology GmbH”. The lens can also be printed using a resin.

The container aperture 121, 221, 321 may have a characteristic dimension D₀ that is the maximum dimension of the container aperture 121, 221, 321. For example, for a circular container aperture 121, 221, 321 D₀ is the diameter of the circle. For a square container aperture 121, 221, 321 D₀ is the diagonal, corner-to-corner distance. The lens 140, 240, 340 may have a characteristic dimension D₁ that is the diameter of the largest cross-section of the lens 140, 240, 340 that is parallel to the container surface. D₁ may be the diameter of the flat side of the lens 140, 240, 340 adjacent to the container surface 421. D₁ may be larger than Do. Preferably, D₁ may be at least twice the size of Do.

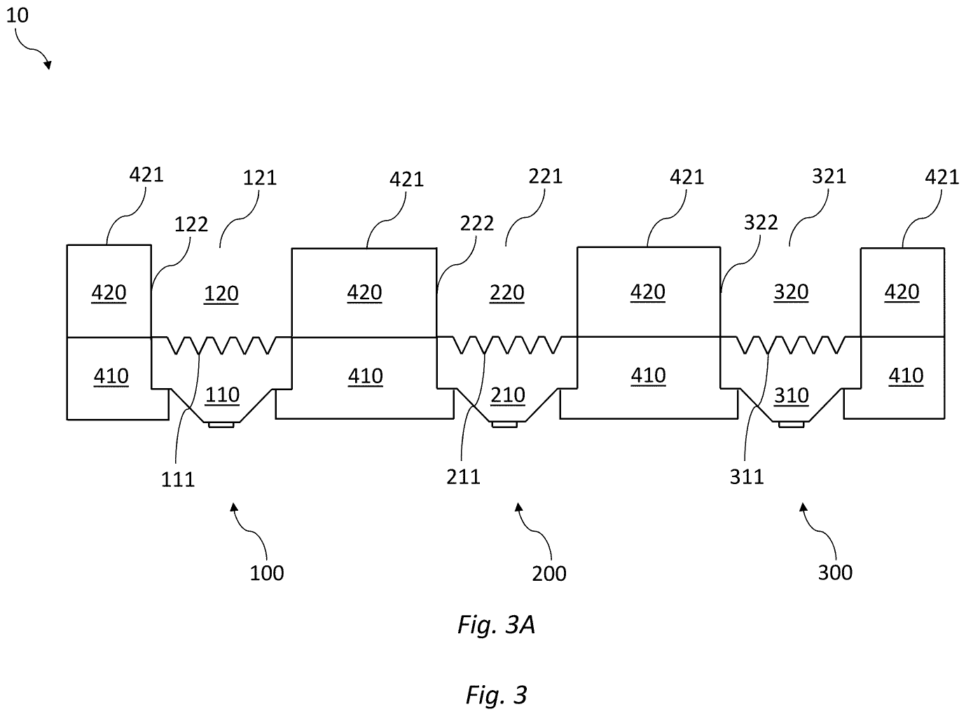

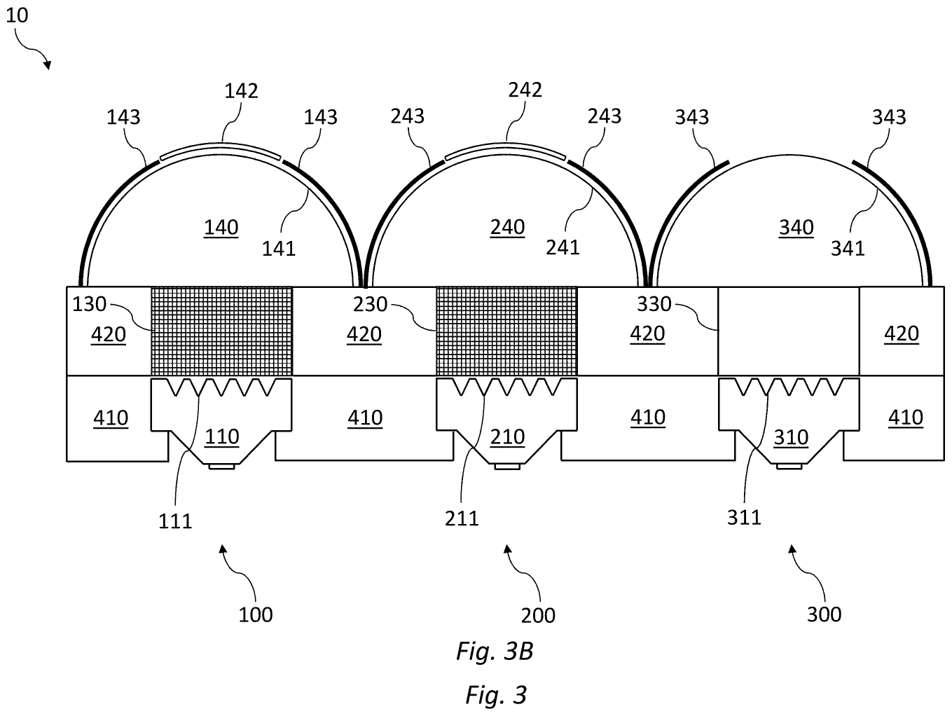

The pixel 10 may comprise at first, second and third sub-pixels 100, 200 and 300 arranged in array wherein at least one sub-pixel is similar to that illustrated in FIG. 2C. For example, with reference to FIG. 3 the sub-pixel 10 may comprise a first and second sub-pixels 100 and 200 that are similar to the sub-pixel 100.

The pixel 10 may comprise a light generating layer comprising an array of semiconductor junctions. Each semiconductor junction is configured to output pump light, such that the light-generating layer may be considered to be an array of pump light LEDs 110, 210 and 310. Each pump light LED 110, 210 and 310 may comprise a semiconductor material with a first doped region and a second doped region (not shown). The interface (not shown) between the first doped region and the second doped region may comprise a plurality of quantum wells and may be configured to generate light when an electrical current is applied. Each pump light LED 110, 210 and 310 may comprise Group III-nitrides. The light generating layer may be fabricated on a substrate, and the side of each pump light LED 110, 210 and 310 that is opposite to the substrate may comprise the light-emitting surface 111, 211 or 311 of the pump light LED 110, 210 or 310.

The pump light LEDs 110, 210, 310 are contained within a base layer 410. The base layer 410 may comprise a light blocking material. The pixel 10 shown in FIG. 3 further comprises a container layer 420 provided on the base layer 410. In an embodiment, the container layer 420 may be made from metal. For example, the container layer 420 may be fabricated from Aluminium. The side of the container layer 420 opposite to the side of the container layer 420 adjacent to the base layer 410 defines a container surface 421 comprising a plurality of container apertures 121, 221 and 321. Each container aperture 121, 221 and 321 defines a container volume 120, 220 and 320 through the container layer 421 to the light-emitting surfaces 111, 211 and 311 of each pump light LED 110, 210 and 310. The inner sidewalls 122, 222 and 322 of the container volumes may surround each of the light-emitting surfaces 111, 211 and 311 of pump light LEDs 110, 210 and 310 such that the container volumes 120, 220 and 320 are generally aligned with the pump light LEDs 110, 210 and 310. The side of the container volume 120, 220 and 320 that is opposite to the container aperture 121, 221 and 321 may comprise the light-emitting surface 111, 211 or 311 of the pump light LED 110, 210 or 310. Each container aperture 121, 221, 321, container volume 120, 220, 320 and inner sidewalls 122, 222, 322 are be similar to those described above with reference to FIG. 2.

With reference to FIG. 3B, each of the sub-pixels 100, 200 and 300 may each further comprise a lens 140, 240, 340 that is provided on the container surface 421 over its respective container aperture 121, 221, 321, as described above. The lens 140, 240, 340 has a convex surface 141, 241, 341 on an opposite side of the lens 140, 240, 340 to the colour converting layer. The lens is provided in order to reduce the amount of converted light that is totally internally reflected at the interface between the sub-pixel and the outside environment. In a certain embodiment, the convex surface 141, 241, 341 may be hemispherical.

At least one of the container volumes 120, 220 and 320 may be filled with a colour converting layer. In the embodiment shown in FIG. 3B, the pump light LEDs 110, 210, 310 may be blue, such that the sub-pixel 100 may be red, the sub-pixel 200 may be green and the sub-pixel 300 may be blue. The first container volume 120 of first sub-pixel 100 may be filled with a first colour converting material 130 that converts pump light to first converted light. The second container volume 220 of second sub-pixel 220 may be filled with a second colour converting material 230 that converts pump light to second converted light. At least one of the container volumes may not include any colour converting material, such that the sub-pixel outputs pump light. For example, the third container volume 320 may be unfilled or may be filled with a transparent material or a translucent material 330 that may be transparent to light at pump wavelengths. For example, translucent material 330 may be transparent to blue visible light. The side of the colour converting layer opposite to the side of the colour converting layer that is adjacent to the light-emitting surfaces of pump light LED 110, 210, 310 may be in the same plane as the container surface 421. The pump light LEDs 110, 210 and 310 may emit blue light, as described above. The first colour converting material 130 may convert blue light to red light, and the second colour converting material 230 may convert blue light to green light. The first and second colour converting materials 130 and 230 may be configured to convert pump light having a wavelength of at least 440 nm and/or no greater than 480 nm. The first colour converting material 130 may be configured to convert the pump light to first converted light having a wavelength of at least 600 nm and/or no greater than 650 nm. The second colour converting material 230 may be configured to convert pump light to second converted light having a wavelength of at least 500 nm and/or no greater than 550 nm.

The pixel 10 may further comprise at least one reflector layer provided on the convex surface 141, 241, 341 of each lens 140, 240, 340. As above, the first sub-pixel 100 may comprise a first reflector 142 provided on the first lens 140 configured to reflect pump light and transmit first converted light, and a second reflector 143 provided on the first lens 140 configured to reflect pump light and first converted light. The second reflector 143 may comprise a reflector aperture, wherein the first reflector 142 fills the reflector aperture.

The second sub-pixel 200 may comprise a third reflector 242 provided on the second lens 240 configured to reflect pump light and transmit second converted light, and a fourth reflector 243 provided on the second lens 240 configured to reflect pump light and second converted light. The fourth reflector 243 may comprise a reflector aperture, wherein the third reflector 242 fills the reflector aperture.

The third sub-pixel 300 may comprise a fifth reflector 343 provided on the third lens 340 configured to reflect pump light, wherein the fifth reflector 343 comprises a reflector aperture.

The first and second reflectors 142 and 143 may conform to portions of the first convex surface 141 of the first lens 140 of the first sub-pixel 100, the third and fourth reflectors 242 and 243 may conform to portions of the second convex surface 241 of the second lens 240 of the second sub-pixel 200, and the fifth reflector 343 may conform to a portion of the third convex surface 341 of the third lens 340 of the third sub-pixel 300.

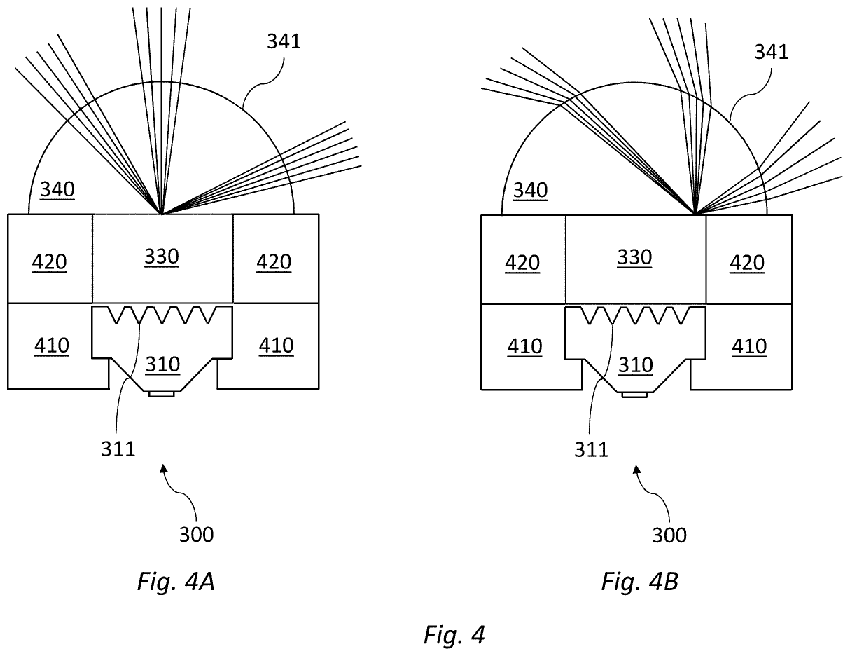

FIG. 4 shows ray tracing diagrams for a sub-pixel 100, wherein the convex surface 341 of the lens 340 is hemispherical. As illustrated in FIG. 4a, light rays emitted from the centre of the container aperture 321 are incident on the convex surface 341 at normal incidence to the convex surface 341. The light rays are transmitted through the convex surface 341 without refraction. As illustrated in FIG. 4b, light rays emitted from closer to the edge of the container aperture 321 are incident on the convex surface 341 with small but finite angles of incidence, and the light rays are refracted away from the normal to the convex surface 341 upon transmission through the convex surface 341. The angle of incidence of the light rays to the normal of the convex surface 341 may be less than 30°. Light rays that are incident on the convex surface 341 with an angle of incidence above a threshold may be totally internally reflected (not illustrated).

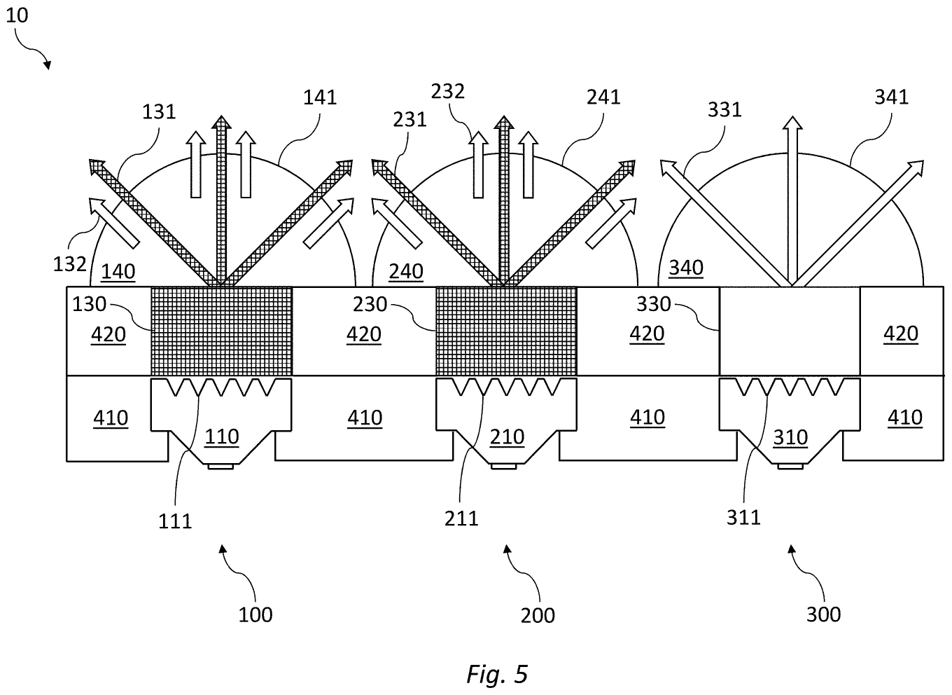

FIG. 5 illustrates the light emission from first, second and third sub-pixels 100, 200 and 300 in the event that they did not have any reflectors on the first, second and third lenses 140, 240 and 340. Referring to first sub-pixel 100, a proportion of the pump light emitted by the pump light LED 110 is converted by the first colour converting material 130 to first converted light, such that the first colour converting material 130 emits first converted light 131 at a first converted wavelength (indicated by arrows with grid pattern). Due to the thin colour converting material used in micro-LEDs, a proportion of the pump light is transmitted through the colour converting material 130 without being converted to first converted light, so pump light 132 is emitted from the first colour converting material 130 at the pump light wavelength (indicated by white arrows). The proportion of pump light that is not converted may be smaller than the proportion of the pump light that is converted to first converted light 131. Similarly, for second sub-pixel 200 a proportion of the pump light emitted by the pump light LED 210 is converted by the second colour converting material 230 to first converted light, such that the colour converting material 230 emits second converted light 231 at a second converted wavelength (indicated by arrows with grid pattern). A proportion of the pump light is transmitted through the second colour converting material 230 without being converted to second converted light, so pump light 232 is emitted from the second colour converting material 230 at the pump light wavelength (indicated by white arrows). Third sub-pixel 300 emits only pump light 331 at the pump light wavelength.

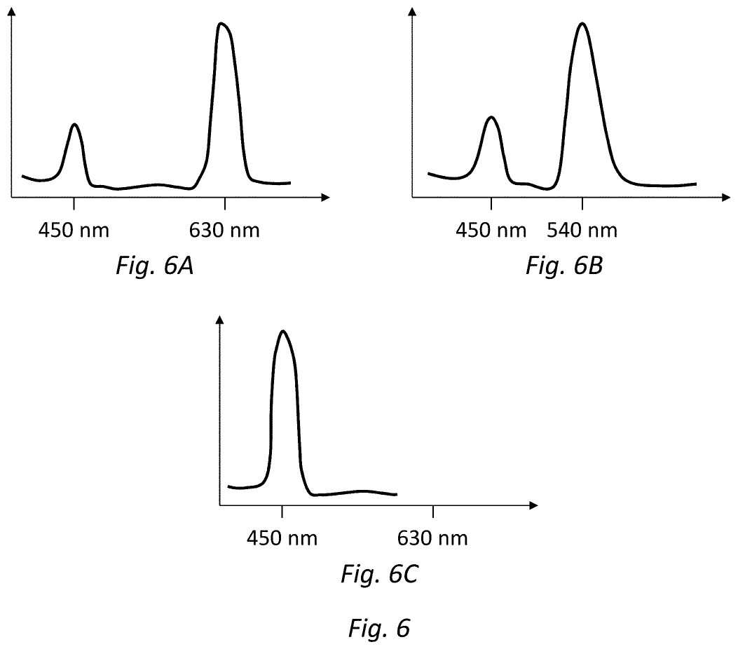

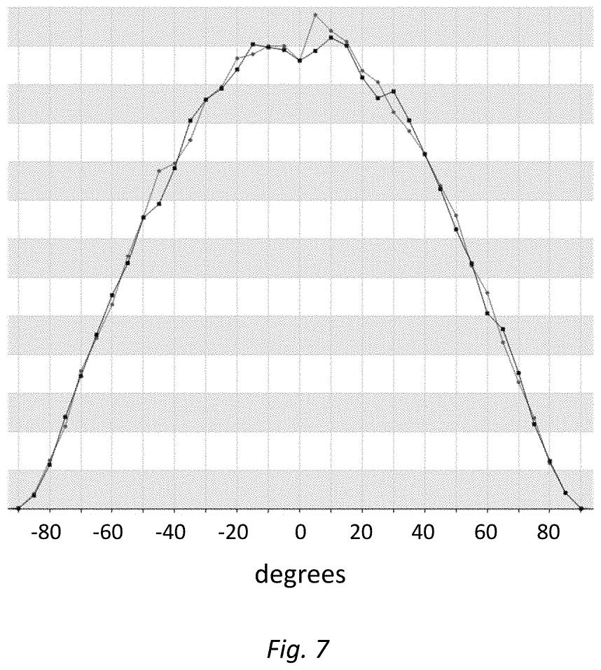

FIG. 6 indicates the emission spectra of light emitted by each of the sub-pixels of FIG. 5. FIG. 6A illustrates the emission spectrum for the first sub-pixel 100, in an embodiment where the first sub-pixel 100 comprises a colour converting material that converts blue pump light to red converted light so the light emitted by the first sub-pixel 100 is expected to be red. The largest intensity is centred at a wavelength 630 nm as expected, but there is a smaller peak centred at 450 nm corresponding to the pump light wavelength. Similarly, the second sub-pixel 200 (FIG. 6B) is expected to be green but there is a smaller peak centred at the pump light wavelength in addition to the peak centred at 540 nm. The third sub-pixel 300 that emits only pump light has a single peak (FIG. 6C). The colour saturation of the first and second sub-pixels 100 and 200 is therefore lower than for the third sub-pixel 300. FIG. 7 shows the emission distribution for the sub-pixel 100 without any reflectors on the lenses, which is close to a Lambertian distribution and has a full-width half-maximum (FWHM) of approximately 120°. The light collection efficiency, for example when the pixel is coupled to an optical system, would therefore be low. For example, for a lens with an acceptance angle of ±10°, only 3% of the light emitted by an LED with a Lambertian distribution will be collected.

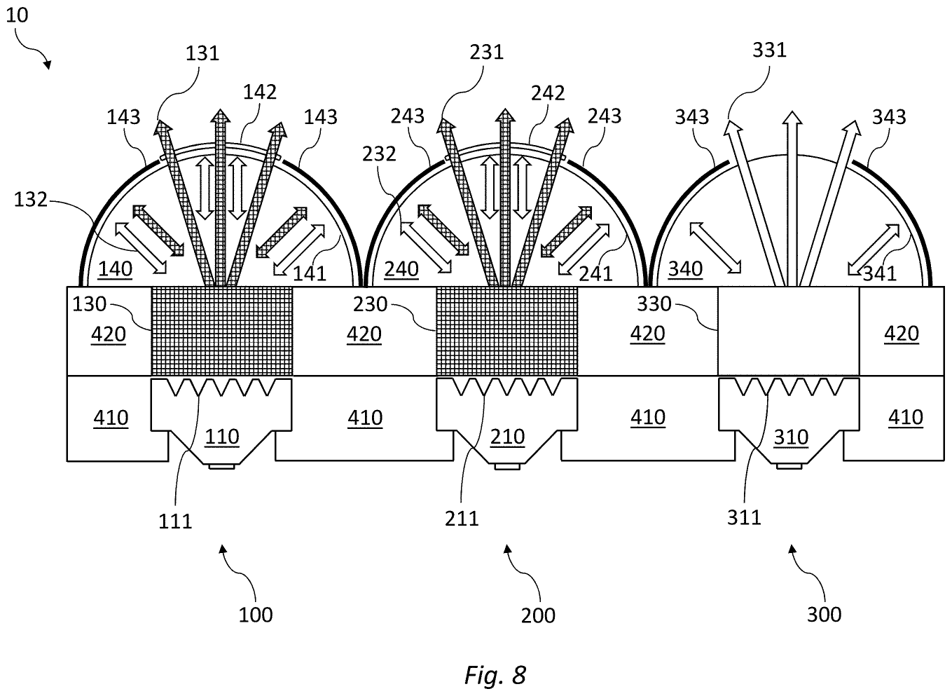

FIG. 8 illustrates the light emission from a pixel 10 in accordance with an embodiment of the disclosure, as described above with reference to FIG. 3B. Referring to the first sub-pixel 100, the first reflector 142 transmits the first converted light 131 and reflects the pump light 132. The second reflector 143 reflects both the first converted light 131 and the pump light 132. The light emitted by the first sub-pixel 100 therefore has a higher colour saturation than a sub-pixel without the reflectors (as illustrated in FIG. 5). The light beam is also collimated as light may only be emitted through the reflector aperture. The reflected pump light may recycled, in that it may be incident on the first colour converting material 130 and have a second chance to be converted to first converted light that may then be emitted by the first colour converting material 130. The first converted light reflected by the second reflector 143 may also be recycled. The container surface 421 and inner sidewalls 122 of the container may be reflective, such that any light that is reflected by the first and second reflectors 142 and 143 may be subsequently reflected at least once such that it is incident on the convex surface 141 of the first lens 142. Thus, the light extraction efficiency may be improved.

Similarly, the second sub-pixel 200 comprises a third reflector 242 that transmits the second converted light 231 and reflects the pump light 232. The fourth reflector 243 reflects both second converted light 231 and the pump light 232. The third sub-pixel 300 comprises only a fifth reflector 343 having a reflector aperture, wherein the fifth reflector 343 reflects pump light and pump light is emitted through the aperture.

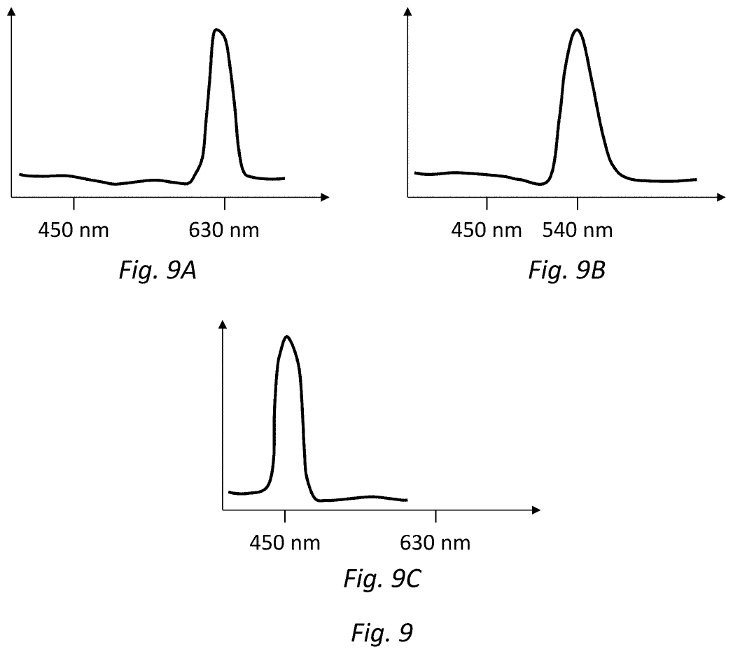

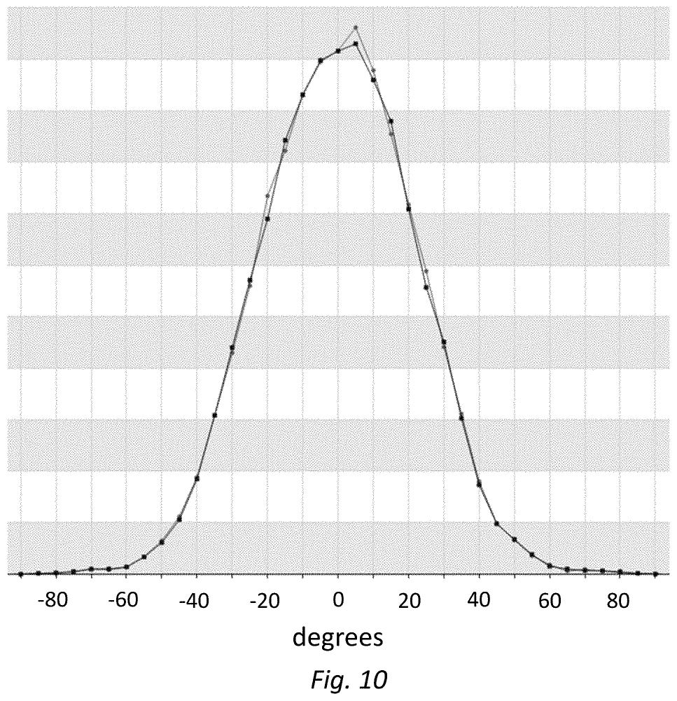

FIG. 9 indicates the emission spectra for each sub-pixel (FIG. 9A corresponds to first sub-pixel 100, FIG. 9B corresponds to second sub-pixel 200 and FIG. 9C corresponds to third sub-pixel 300). In this embodiment the first and second sub-pixels 100 and 200 comprise colour converting materials that convert blue pump light to red and green light respectively. The third sub-pixel 300 does not comprise colour converting material and emits blue light. In contrast to the emission spectra shown in FIG. 6, each of the three sub-pixels has only a single peak emission. In particular, the first and second sub-pixels 100 do not have peaks in their emission spectra at blue wavelengths, indicating that minimal pump light has been emitted. FIG. 10 shows the emission distribution for a sub-pixel 100 similar to that shown in FIG. 8. The emission distribution is narrower than that in FIG. 7, due to light only being emitted via the reflector aperture, and has a FWHM of approximately 50°.

The first, second and third lenses 140, 240 and 340 in the embodiment described above are hemispherical in shape. Therefore, light emitted from the centre of the container aperture 121, 221, 321 is incident on the convex surface 141, 241, 341 of the lens 140, 240, 340 at the normal to the convex surface 141, 241, 341. Any light that is reflected has a reflected path that is the same as the incident path, such that the reflected light is incident at the container aperture 121, 221, 321 at the same point from which it was emitted. This avoids the reflected light being focused on particular areas and away from other areas and may thereby allow for more efficient recycling of reflected light, to increase light extraction efficiency of the sub-pixel 100, 200, 300. For example, the colour converting material 130, 230 may not convert all pump light to converted light, and may emit some pump light. This pump light 132, 232 may be reflected by one of the reflectors 142, 143, 242, 243 on the convex surface 141, 241 of the lens 140, 240 along its incident path, such that re-enters the colour converting material 130, 230. The pump light then may be converted to converted light on its second journey within the colour converting material 130, 230, and subsequently emitted from the colour converting material 130, 230 as converted light 131, 231. Converted light may also be reflected from one of the reflectors 143, 243 such that it re-enters the colour converting material 130, 230. The converted light is scattered via Rayleigh scattering. Up to 50% of light that enters the container volume 120, 220 via the container aperture 121, 221 may be emitted via the container aperture 121, 221 after subsequent reflection by the inner sidewalls 122, 222 or by a coating (described later) on the light-emitting surface 111, 211 of the pump light LED 110, 210. In the absence of a colour converting material, as in the third sub-pixel 300, up to 70% of light that enters the container volume 320 may be emitted via the container aperture 321.

Light that is emitted from a point that is not at the centre of the container aperture may be incident on the convex surface 141, 241, 341 at a finite angle to the normal to the convex surface 141, 241, 341, so that if the light is reflected the reflected path is not the same as the incident path. The reflected light may be incident on the container aperture at a different point from which it was emitted. Some reflected light may be incident on the container surface and reflected for a second time.

Pump light that is reflected by one of the reflectors 142, 143, 242, 243 may in some cases be reflected from the container surface 421 or may not be converted to converted light on its second journey through the colour converting material 130, 230. The pump light may then be incident on the convex surface 141, 241 for a second time and may again be reflected by one of the reflectors 142, 143, 242, 243 on the convex surface 141, 241 of the lens 140, 240. The pump light that has been reflected at the convex surface 141, 241, 341 for a second time may be reflected along its incident path or otherwise such that it re-enters the colour converting material 130, 230 for a third time or such that it is reflected from the container surface 421. This cycle may in theory perpetuate for as long as the light remains unconverted. A location of emission from the colour converting material 130, 230 may be different for each journey because of different reflections within the colour converting material 130, 230 such that the light may not follow the same route through the lens on each occasion. Similarly, converted light may be reflected from one of the second or fourth reflectors 143, 243 and may either be incident on the colour converting material 130, 230 for a second time or may be reflected from the container surface 421. The converted light that is emitted from the colour converting material 130, 230 for the second time or reflected from the container surface 421 may be incident on the convex surface 141, 241 of the lens 140, 240 for a second time. In the event that the converted light is incident on the reflector aperture the converted light may be transmitted through the first or third reflector 142, 242 and may exit the lens. In the event that the converted light is not incident on the reflector aperture, the converted light may be reflected from the second and fourth reflectors for a second time. The cycle may in theory perpetuate until the converted light is incident on the reflector aperture and exits the sub-pixel.

As described above, the inner sidewalls 122, 222 of the container volume 120, 220 are reflective such that the light re-entering the colour converting material may be reflected at least once and may subsequently be emitted through the container aperture. Light emitted from the edge of the container aperture 121, 221, 321 may be incident on the convex surface 141, 241, 341 of the lens 140, 240, 340 at a finite angle to the normal to the convex surface 141, 241, 341. The reflected path of the light may therefore not be the same as the incident path. For efficiency of recycling the light, it is therefore beneficial for the characteristic dimension D₀ of the container aperture to be smaller than the characteristic dimension of the lens D₁ so that the light emitted from the edge of the container aperture 121, 221, 321 may be incident on the convex surface 141, 241, 341 of the lens 140, 240, 340 close to the normal to the convex surface 141, 241, 341. Preferably, D₁ may be at least twice the size of D₀.

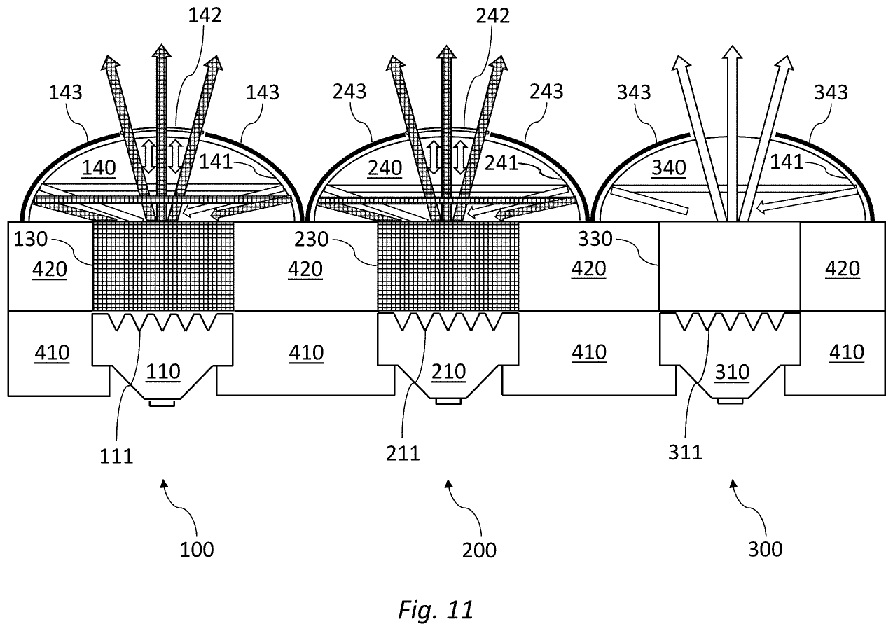

In an embodiment where the lenses 140, 240 and 340 are not hemispherical, the behaviour of light reflected may be different. In the example described above, in which the lenses 140, 240 and 340 are hemispherical, light that is reflected at the convex surface 141, 241, 341 is reflected on a path close to the incident path such that the reflected light is incident on the container aperture 121, 221, 321. In an alternative embodiment, shown in FIG. 11, the lenses 140, 240, 340 may be elliptical or parabolic. Considering first sub-pixel 100, light emitted from the centre of the container aperture 121 at a small angle to the normal to the container aperture may be incident on the first reflector 142 at an angle close to the normal to the convex surface 141. If reflected, the reflected path is close to the incident path and the light is incident on the container aperture 121. Light emitted from the centre of the container aperture 121 that is emitted at a larger angle to the normal to the container aperture 121 may be incident on a part of the second reflector 143 where the radius of curvature of the convex surface 141 is smaller than at the first reflector 141. The angle of incidence of the light on the convex surface 141 may result in a reflected path that is not similar to the incident path, such that the reflected light is incident on the convex surface and may be reflected a second time. The subsequently reflected light may then be incident on the container aperture.

In another embodiment, the third lens 340 of the third sub-pixel 300 may be a different shape to the first and second lenses 140 and 240 of the first and second sub-pixels 100 and 200. In an embodiment where the third container volume 320 is empty (rather than containing a translucent material 330), the distribution of light rays emitted from the container aperture 321 may be different from the distribution of light rays emitted from the container apertures of sub-pixels 100 and 200 in which the container volumes 120 and 220 are filled with colour converting materials 130 and 230. It may be appropriate, for example, to have hemispherical lenses 140 and 240 for first and second sub-pixels 100 and 200, but an elliptical or parabolic lens 340 for third sub-pixel 300.

For simplicity, the structure of a sub-pixel of this embodiment will be described in more detail with reference only to sub-pixel 100. It will be understood that the second sub-pixel 200 is similar to the first sub-pixel 100 in every way except that the second colour converting material 230 may convert pump light to a different converted wavelength than the first colour converting material.

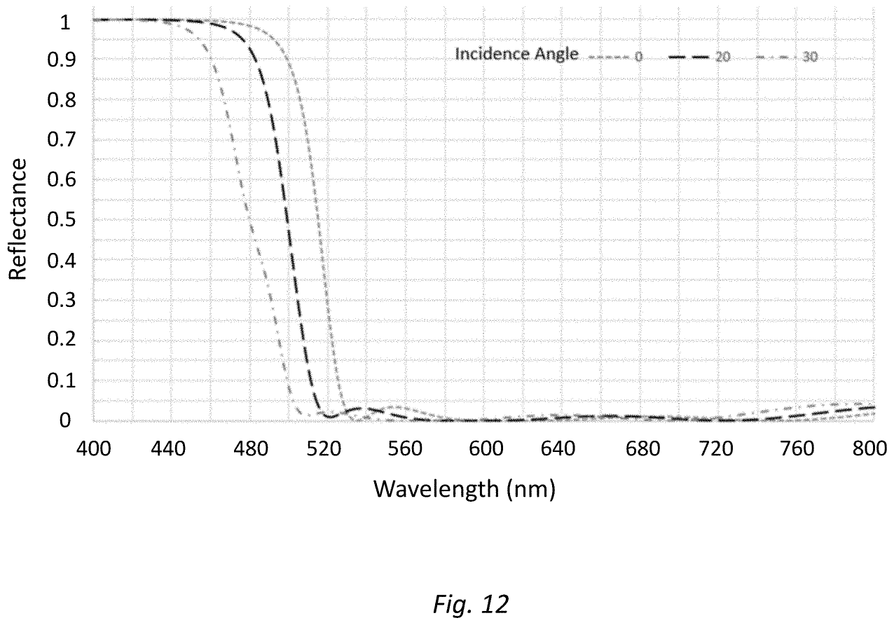

The second reflector 143 may be made from a metal, such that it reflects all visible light. For example, the second reflector 243 may made from Silver or Aluminium. The first reflector 142 may act similarly to a band stop filter, such that the first reflector has a stop-band over a range of wavelengths from a lower stop-band wavelength to an upper stop-band wavelength (λ₁) in which substantially all light is reflected by the first reflector 142. The reflectance of a first reflector 142 is shown in FIG. 12. The stop-band is centred on a central wavelength (λ₀) such that the upper stop-band wavelength (λ₁) and the lower stop-band wavelength are equidistant from the central wavelength. For wavelengths shorter than the lower stop-band wavelength, the first reflector 142 has a lower pass band, in which light is generally transmitted through the first reflector 142. Similarly, for wavelengths longer than the upper stop-band wavelength (λ₁), the first reflector 142 has an upper pass band, in which light is generally transmitted through the first reflector 142. FIG. 12 illustrates reflectance of a first reflector 142 with central wavelength 420 nm (λ₀), such that the lower stop-band wavelength is smaller than the wavelength range plotted. The dotted and dashed lines show the reflectance of the first reflector 142 for different angles of incidence (dotted line corresponds to an angle of incidence of 30°, dashed line corresponds to 20° and dotted-dashed line corresponds to 0°). For reference, the emission of a blue LED would be centred at 455 nm.

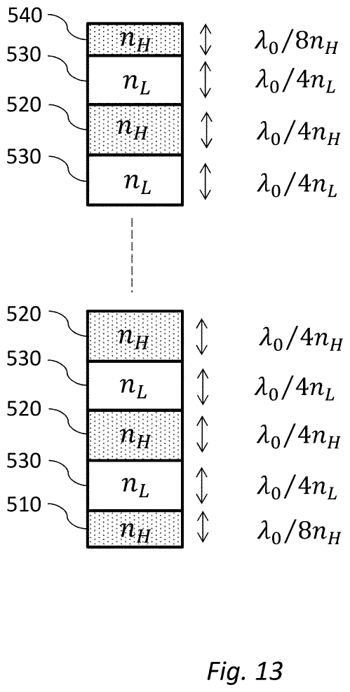

The first reflector 142 may comprise a laminate structure, as disclosed in GB 1911008.9 and described in the following. The structure is illustrated in FIG. 13. The first reflector 142 comprises a first interface layer 510, a plurality of alternating first and second laminate layers 520 and 530, and a second interface layer 540. The plurality of alternating first and second laminate layers 520 and 530 form a central portion of the first reflector 142. The first laminate layer (H) 520 has a first refractive index (n_{H}), and the second laminate layer (L) 530 has a second refractive index (n_{L}) wherein the first refractive index is higher than the second refractive index. The first refractive index is higher than the second index. In some embodiments, the first refractive index is at least 2 and the second refractive index is no greater than 1.8. For example, the first laminate layer (H) 520 may comprise TiO₂ with a refractive index of about 2.6, and the second laminate layer (L) 530 may comprise SiO₂ with a refractive index of about 1.5.

The first laminate layer (H) has a first thickness (t_{H}), and the second laminate layer (L) has a second thickness (t_{L}). The thickness of each laminate layer is a thickness measured in a direction normal to a major surface of the respective laminate layer. In order to tailor the reflectance characteristics of the first reflector 142 to reflect the pump light, each of the first and second laminate layers (L) has a thickness refractive index product of one quarter of the central wavelength of the stop-band. That is to say, for the first laminate layer (H) the product of the first thickness (t_{H}) and the first refractive index (n_{H}) is equal to λ₀/4. Similarly, for the second laminate layer (L) the product of the second thickness (t_{L}) and the second refractive index (n_{L}) is equal to λ₀/4. In general, the first laminate layer (H) 520 may have a first thickness (t_{H}) of between 5 nm and 50 nm. The second laminate layer (L) 530 may have a second thickness (t_{L}) of between 10 nm and 100 nm.

A plurality of first laminate layers (H) 520 and second laminate layers (L) 530 may be stacked on top of each other in an alternating manner in order to form a central part of the first reflector 142. The central part of the first reflector 142 may be formed of at least three layers, with the second laminate layer (L) 530 forming the outer layers of the central arrangement (an LHL arrangement). In some embodiments, at least 5 alternating layers may be provided the second laminate layer (L) 530 forming the outer layers of the central arrangement (LHLHL). In some embodiments, 17 alternating layers may be provided with the second laminate layer (L) 530 forming the outer layers of the central arrangement (LHL . . . LHL).

On opposite sides of the central part of the first reflector 142, first and second interface layers 510 and 540 are provided. Each of the first and second interface layers 510 and 540 may comprise the same material as the first laminate layer (H) 520, and therefore the first and second interface layers 510 and 540 may have the same refractive index (n_{L}) as the first laminate layer (H) 520. The first and second interface layers may have respective third and fourth refractive indexes (n₃, n₄) and respective third and fourth thicknesses (t₃, t₄). The first and second interface layers may have a thickness refractive index product equal to one eighth of the pump light wavelength (e.g. n₃t₃=λ₀/8).

When the layers of the first reflector 142 (the first and second laminate layers 520 and 530 and the first and second interface layers 510 and 540) have a refractive index that is dependent on the wavelength of light, the refractive index of the layer for the purpose of this disclosure is considered to be the refractive index of the layer at the central wavelength (λ₀) of the first reflector 142. The layers of the first reflector 142 have thicknesses configured to reflect pump light having a wavelength of 455 nm. The central wavelength λ₀ of the first reflector 142 is 420 nm.

The reflectance of the first reflector 142 shown in FIG. 12 is according to an embodiment in which the central part of the first reflector 142 comprises 13 alternating laminate layers (520 and 530) of SiO₂ and TiO₂, and two interface layers (510 and 540) of TiO₂. In a specific embodiment, the thicknesses may be as follows:

| | | Thickness |
|---|---|---|
| Layer | Material | (nm) |
| 1 | TiO2 | 20 |
| 2 | SiO2 | 71 |
| 3 | TiO2 | 40 |
| 4 | SiO2 | 71 |
| 5 | TiO2 | 40 |
| 6 | SiO2 | 71 |
| 7 | TiO2 | 40 |
| 8 | SiO2 | 71 |
| 9 | TiO2 | 40 |
| 10 | SiO2 | 71 |
| 11 | TiO2 | 40 |
| 12 | SiO2 | 71 |
| 13 | TiO2 | 40 |
| 14 | SiO2 | 71 |
| 15 | TiO2 | 20 |

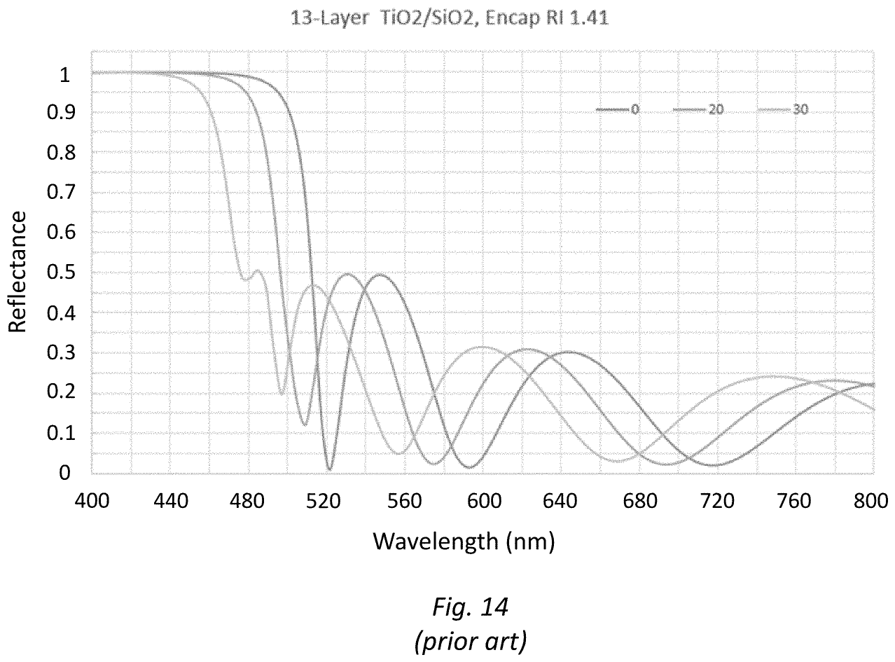

The first reflector 142 may also comprise a Distributed Bragg Reflector (DBR). An example of reflectance of a DBR is shown in FIG. 14. For the upper pass band of a first reflector 142 with a laminate structure as described above, the reflectance may be lower than for the DBR. In particular, the reflectance of the first reflector 142 with a laminate structure in the green through red visible light spectrum is below 5% for angles of incidence between 0° and 30°. Accordingly, the first reflector 142 with a laminate structure (FIGS. 12 and 13) will not reflect as much converted light as the DBR of FIG. 14, regardless of the angle of incidence. Accordingly, a green or red LED incorporating first reflector 142 with a laminate structure (FIGS. 12 and 13) will more efficiently extract converted light compared to a DBR (FIG. 14).

In some embodiments, the LED array 10 may also incorporate a converted light reflector laminate. The converted light reflector laminate may be provided between a pump light LED 110, 210 and a colour converting layer of a sub-pixel 100, 200. A converted light reflector laminate may be provided to increase the proportion of converted light extracted from the container volume 120, 220 by reflecting the converted light towards the convex surface 141, 241 of the lens 140, 240. The converted light reflector laminate may also be configured to transmit pump light generated in the pump light LED 10, 210, so as to not reduce the overall efficiency of the LED by reflecting pump light back towards the pump light LED 110, 210 (away from the container volume 120, 220). As such, the converted light reflector laminate may also be a form of band-stop filter configured to transmit pump light and reflect converted light. As such, the converted light reflector laminate has a stop-band configured to reflect the converted light centred on a second wavelength. In some embodiments, the second wavelength may be equal to the converted light wavelength, but in other embodiments, the converted light reflector laminate may be configured such that, for example, the converted light wavelength falls between the second wavelength and a lower stop-band wavelength. The converted light reflector laminates may comprise a third interface layer, a plurality of alternating third and fourth reflector layers and a fourth interface layer. The third interface layer may have a fifth refractive index (n₅) and a fifth thickness (t₅).

The plurality of alternating third and fourth reflector layers form a central portion of the converted light reflector laminate. The third reflector layer (H) has a sixth refractive index n₆ and the fourth reflector layer (L) has a seventh refractive index n₇. The third reflector layer (H) has a sixth thickness t₆ and the fourth reflector layer (L) has a seventh thickness t₇. The fifth and seventh refractive indexes are lower than the sixth refractive index. In some embodiments, the sixth refractive index is at least 2, while the fifth and seventh refractive indexes are no greater than 1.8. For example, the third reflector layer (H) may comprise TiO2 (refractive index of about 2.60 at 420 nm), and the fourth reflector layer (L) may comprise SiO2 (refractive index of about 1.48 at 420 nm).

In order to tailor the reflectance characteristics of the converted light reflector laminate to reflect the converted light, each of the third and fourth reflector layers has a thickness refractive index product in the direction normal to the light emitting surface 111, such that a stop-band of the converted light reflector laminate is configured to reflect the converted light. For example, in some embodiments, the thickness refractive index product may be chosen to be equal to one quarter of the converted light wavelength of the respective colour converting material. For example, in an embodiment in which the colour converting material is configured to convert pump light to converted light having a wavelength of 610 nm, each of the third reflector layers (H) may have a thickness of about 58 nm and each of the fourth reflector layers (L) may have a thickness of 101 nm.

Where the layers of the converted light reflector laminate (i.e. the third and fourth reflector layers and the third and fourth interface layers) have a refractive index which is dependent on the wavelength of light, the refractive index of the layer for the purpose of this disclosure is considered to be the refractive index of the layer at the second wavelength (central wavelength) of the converted light reflector laminate. A plurality of fourth reflector layers (L) and a plurality of third reflector layers (H) are stacked on top of each other in an alternating manner in order to form a central part of the converted light reflector laminate. The central part of the converted light reflector laminate may be formed from at least 3 layers, with the third reflector layer (H) forming the outer layers of the central part (an HLH arrangement). In some embodiments at least 5 alternating layers may be provided (HLHLH). In an example, the central part comprises 19 alternating layers (HLH . . . HLH).

On opposite sides of the central part of the converted light reflector laminate, third and fourth interface layers are provided. Each of the third and fourth interface layers may comprise the same material as the third reflector laminate (i.e. the third and fourth interface layers may have the same refractive index as the third refractive index). The third and fourth interface layers may have a thickness refractive index product equal to one eighth of the central wavelength.

In some embodiments, a converted light reflector laminate may be provided for only sub-pixels incorporating a colour converting material 130, 230. Alternatively, the converted light reflector laminate may be provided to cover all of the light emitting surfaces 111, 211, 311 of each of the pump light LEDs 110, 210, 310. By providing the converted light reflector laminate across all pump light LEDs 110, 210, 310, it may be possible to form the converted light reflector laminate with reduced patterning steps, thereby making the LED array more efficient to fabricate.

In some embodiments, an antireflection layer may be provided over the first reflector 142, 242. The antireflection layer is configured to reduce reflection of the converted light at the interface between the second interface layer of the first reflector 142, 242 and the external surroundings of the pixel 10 (typically air). In some embodiments, the antireflection layer comprises a material having a refractive index less than a refractive index of the second interface layer of the first reflector 142, 242. For example, the antireflection layer may comprise a material having a refractive index of less than 1.6. For example the antireflection layer may comprise SiO₂. In some embodiments, the antireflection layer has a thickness of one quarter of the converted light wavelength. As such, the thickness of the antireflection layer may be configured to reduce reflection of the converted light transmitted by the first reflector 142, 242. Accordingly, the antireflection layer may be provided in order to further increase the converted light extraction efficiency of the LED.

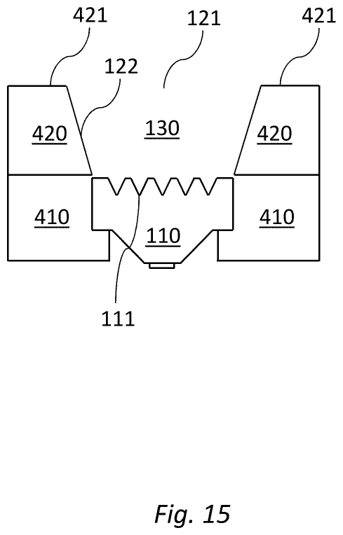

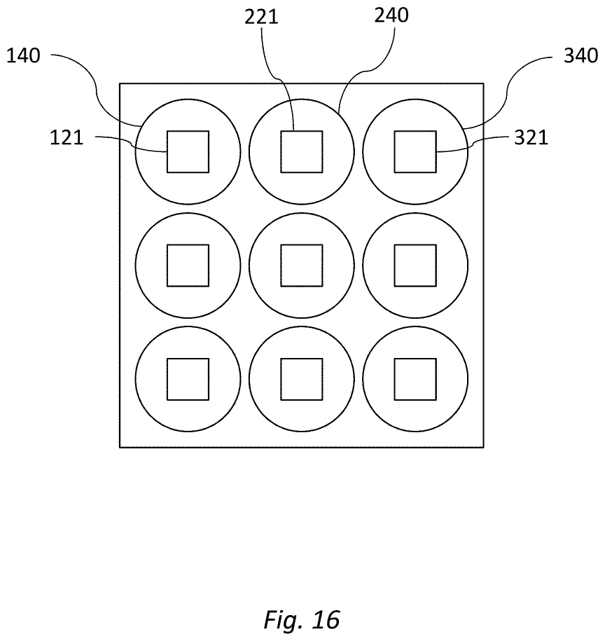

In the embodiments described above, the inner sidewalls 122 are normal to the container surface 421. For example, for a circular container aperture 121 the container volume 120 would be cylindrical. In alternative embodiments, the inner sidewalls 122 may be sloped such that the area of the container aperture 121 is larger than the area of the side of the container volume 120 at which light emitted from the light-emitting surface 111 of the pump light LED 110 enters the container volume 120. The angle between the inner sidewalls 122 and the light-emitting surface 111 may be acute. An example is illustrated in FIG. 15, shown without the lens 140 for simplicity. As before, the container aperture 121 may be any regular or irregular polygon and the number of inner sidewalls 122 may be equal to the number of inner sidewalls 122. For example, the shape of the container volume may resemble a truncated inverted cone or a truncated inverted square pyramid

A sub-pixel that has a container volume 120, 220, 320 with sloped inner sidewalls 122, 222, 322 may have increased optical efficiency as a greater portion of light that is incident on the inner sidewalls 122, 222, 322 and reflected may be directed towards the container aperture 121, 221, 321. The sloped inner sidewalls 122, 222, 322 will also result in a larger pitch of a sub-pixel array and therefore lower display resolution, since the container aperture 121, 221, 321 must necessarily be larger than the light-emitting surface 111, 211, 311 of the pump light LED 110, 210, 310. The angle of the inner sidewalls 122, 222, 322 with respect to the normal to the container surface 421 is therefore a compromise between increased optical efficiency and reduced display resolution. In some embodiments, the inner sidewalls 122, 222, 322 for each container volume 120, 220, 320 may be sloped relative to the normal to the container surface 421 at an angle of at least 35°. By providing an angle of at least 35°, each container aperture 121, 221, 321 may have an area such that a pixel pitch of the LED array does not become excessive. In some embodiments, the sidewalls 122, 222, 322 for each container volume 120, 220, 320 may be sloped relative to the normal to the container surface 421 at an angle no greater than 85°. In some embodiments, providing the inner sidewalls 122, 222, 322 with an angle of no greater than 85°, or no greater than 60°, may increase the optical efficiency of the LED, as a greater proportion of converted light may be directed towards the container aperture 121, 221, 321. As described above, the inner sidewalls 122, 222, 322 may be reflective such that a greater proportion of light which is incident on the inner sidewalls 122, 222, 322 will be reflected back into the container volume 120, 220, 320 (relative to light absorbent sidewalls). Thus, a greater proportion of converted light, which may be generated in all directions from the colour converting material, may be extracted from the LED. In the event that the container layer 420 is not made from metal, the inner sidewalls 122, 222, 322 may be coated with a reflective material such as a thin film metal, for example Al or Ag.

FIG. 16 illustrates a plan view of an embodiment of the disclosure comprising nine sub-pixels in an array, wherein the container apertures 121, 221, 321 are square and the cross section of the lenses 140, 240, 340 are circular. The array may comprise more or less than nine sub-pixels. In an embodiment, a display may comprise pixels 10 each comprising a first sub-pixel 100 that is red, a second sub-pixel 200 that is green and a third sub-pixel 300 that is blue. In other embodiments, the colours of the sub-pixels may be different. In an embodiment, the pixel 10 may be monochrome and may comprise a plurality of sub-pixels that have blue pump light LEDs and the same colour converting material.

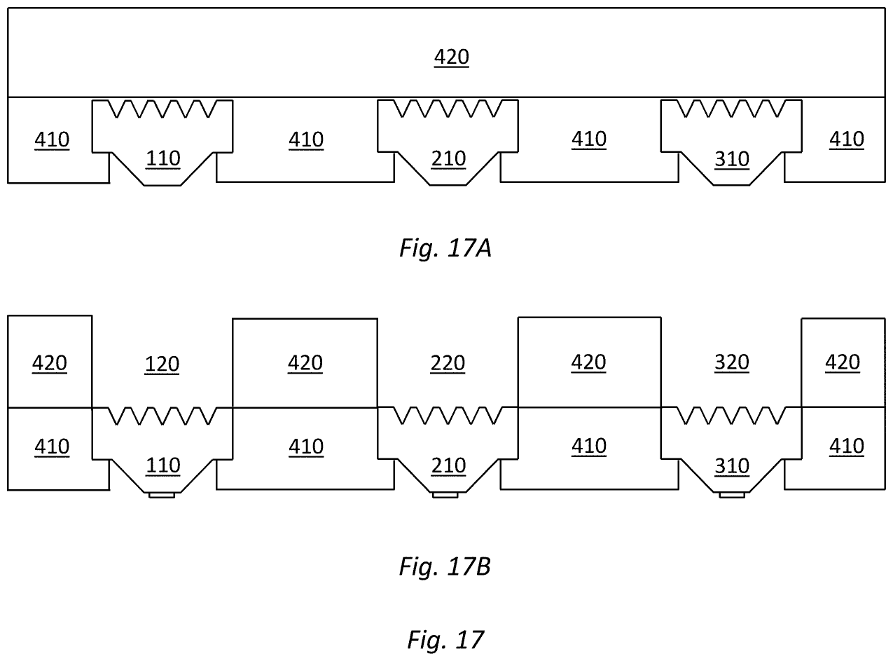

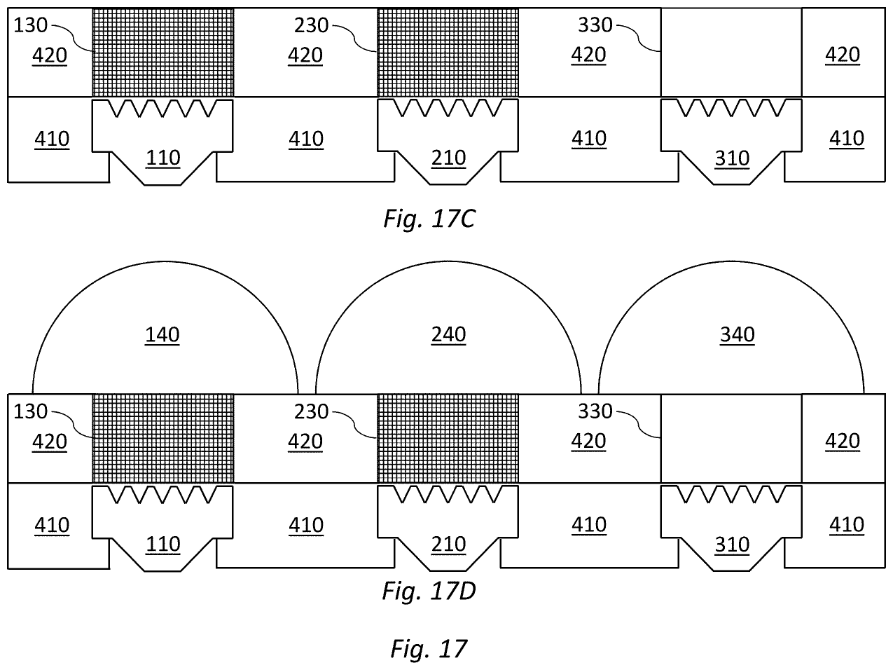

With reference to FIG. 17, the method of fabrication of a pixel 10 in accordance with an embodiment of this disclosure may be as follows. A container layer 420, for example Aluminium, may be deposited on an LED wafer of blue LEDs (FIG. 17A). The deposition may be an evaporation method or physical vapour deposition. The container layer 420 may then be patterned by dry etching using a hard mask pattern, to achieve the container volumes (FIG. 17B). The container volumes may be filled with a colour converting material (for red and green sub-pixels) or a translucent material (for blue pixels). This may be achieved using a nano-printing method or by lithography, wherein the colour converting or translucent material is mixed with a photo-definable matrix material. A planarization step removes excess material. The filled container volumes are illustrated in FIG. 17C. Dome lenses may then be fabricated using nano imprint lithography (NIL) (FIG. 17D).

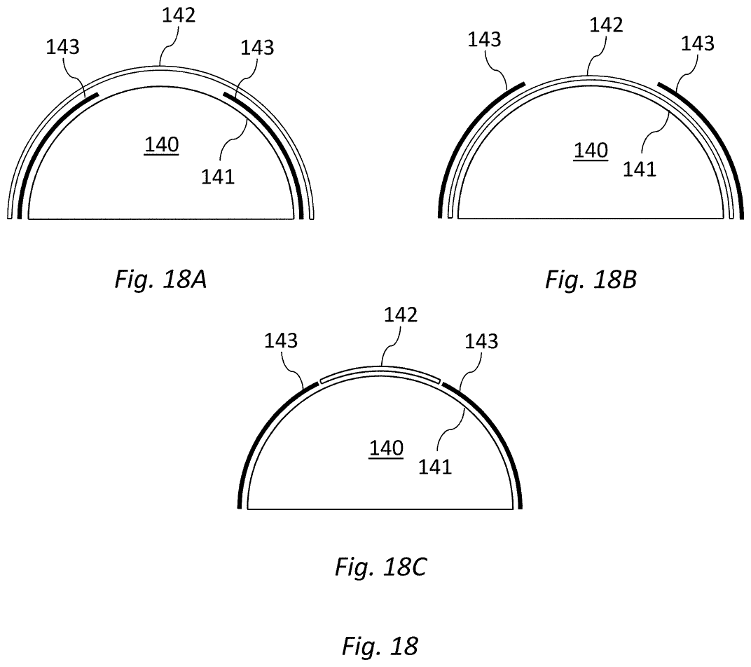

The reflector layers may be added in several ways. The results are shown in FIG. 18, which illustrates the lens 140 and reflectors 142, 143 of a first sub-pixel 100. In a first method, all dome lenses are partially metallised using an evaporation method (to give the second, fourth and fifth reflectors comprising a reflector aperture). The laminate reflector (first and third reflectors that transmit converted light and reflect pump light) is then applied to all sub-pixels except the blue sub-pixel using atomic layer deposition. As illustrated in FIG. 18A, this results in the second reflector being positioned between the lens and the first reflector. In a second method, the laminate reflector is deposited first, then the lenses are partially metallized. As illustrated in FIG. 18B, this results in the first reflector 142 being between the lens 140 and the second reflector 143. The third sub-pixel (blue) may be omitted when depositing the laminate reflector either by using a mask or by etching the deposited layer away after deposition. The dome lenses of the first and second sub-pixels (red and green) may be fully coated. In another embodiment, the laminate reflector may be provided only in the reflector aperture of the metallised reflector, illustrated in FIG. 18C, such that the dome lenses of the first and second sub-pixels are partially coated by the laminate reflector. In another embodiment, the dome lenses may be partially coated in the laminate reflector such that there is an overlap between the laminate reflector and the metallised reflector that may be finite but smaller than that illustrated in FIG. 18A or 18B.

1. A pixel comprising a first sub-pixel, wherein the first sub-pixel comprises:
an LED layer comprising a light-emitting material configured to emit pump light from a light-emitting surface, the pump light having a pump wavelength;
a container layer having a container surface comprising a first container aperture that defines a first container volume extending through the container layer;
a first colour converting layer provided in the first container volume and configured to receive light from the light-emitting surface of the LED layer, wherein the first colour converting layer comprises a first colour converting material that is configured to absorb light at the pump wavelength and emit first converted light of a first converted wavelength;
a first lens provided on the container layer over the first container aperture, comprising an inner side adjacent to the colour converting layer and an outer side, wherein the outer side comprises a first convex surface;
a first reflector assembly adjacent the outer side of the first lens and conforming to the first convex surface, the first reflector assembly comprising:
a first reflector configured to reflect light at the pump wavelength and transmit light at the first converted wavelength; and
a second reflector configured to reflect light at both the pump wavelength and the first converted wavelength;
wherein the second reflector comprises a first sub-pixel reflector aperture and wherein the first reflector fills the first sub-pixel reflector aperture.

2. The pixel of claim 1 further comprising a second sub-pixel, wherein the second sub-pixel comprises:
an LED layer comprising a light-emitting material configured to emit pump light from a light-emitting surface, the pump light having the pump wavelength;
a container layer having a container surface comprising a second container aperture that defines a second container volume extending through the container layer;
a second colour converting layer provided in the second container volume and configured to receive light from the light-emitting surface of the LED layer, wherein the second colour converting layer comprises a second colour converting material that is configured to absorb light at the pump wavelength and emit second converted light of a second converted wavelength;
a second lens provided on the container layer over the second container aperture, comprising an inner side adjacent to the colour converting layer and an outer side, wherein the outer side comprises a second convex surface;
a second reflector assembly adjacent the outer side of the second lens and conforming to the second convex surface, the second reflector assembly comprising:
a third reflector configured to reflect light at the pump wavelength and transmit light at the second converted wavelength; and
a fourth reflector configured to reflect light at both the pump wavelength and the second converted wavelength;
wherein the fourth reflector comprises a second sub-pixel reflector aperture and wherein the third reflector fills the second sub-pixel reflector aperture.

3. The pixel of claim 2 further comprising a third sub-pixel that emits light at the pump wavelength, wherein the third sub-pixel comprises:
an LED layer comprising a light-emitting material configured to emit pump light from a light-emitting surface, the pump light having the pump wavelength;
a container layer having a container surface comprising a third container aperture that defines a third container volume through the container layer;
a lens provided on the container layer over the third container aperture, comprising an inner side adjacent to the container layer and an outer side, wherein the outer side comprises a third convex surface;
a third reflector assembly adjacent to the outer side of the third lens and conforming to the third convex surface, the third reflector assembly comprising:
a fifth reflector configured to reflect pump light, wherein the fifth reflector comprises a third sub-pixel reflector aperture.

4. The pixel of claim 1 wherein a central axis of the first reflector and a central axis of the second reflector are aligned with a central axis of the convex surface.

5. The pixel of claim 1 wherein the first reflector comprises a laminate structure.

6. The pixel of claim 5 wherein the first reflector comprises alternating layers of higher and lower refractive index.

7. The pixel of claim 6 wherein the first reflector comprises a plurality of layers of TiO₂ and SiO₂.

8. The pixel of claim 1 wherein the first reflector comprises a distributed Bragg reflector.

9. The pixel of claim 1 wherein the second reflector comprises a metallic material.

10. The pixel of claim 1, wherein the first container volume comprises reflective inner sidewalls.

11. The pixel of claim 1, wherein the area of the first container aperture is at least equal to the area of the light-emitting surface of the LED layer.

12. The pixel of claim 1, wherein an inner sidewall of the first container volume forms an angle relative to the normal to the light-emitting surface of the LED layer of at least 35° and no greater than 85°, or preferably no greater than 60°.

13. The pixel of claim 12, wherein the first container aperture is circular such that the corresponding container volume resembles a truncated inverted cone, or wherein the first container aperture is rectangular such that the corresponding container volume resembles a truncated inverted square pyramid.

14. The pixel of claim 1, wherein the first lens is hemispherical, elliptical, or parabolic.

15. (canceled)

16. The pixel of claim 1 wherein a characteristic dimension of the lens is at least twice as large as a characteristic dimension of the aperture in the plane of the container layer.

17. The pixel of claim 1, further comprising a converted light reflector laminate at an interface between the LED layer and the colour converting layer.

18. (canceled)

19. The pixel of claim 1 wherein the reflectance of the first reflector to light at the pump wavelength is more than 95%, or preferably 100%.

20. The pixel of claim 1 wherein the reflectance of the first reflector to light at the converted wavelength is less than 10%, or preferably less than 5%.

21. (canceled)

22. The pixel of claim 1 wherein the first colour converting material comprises a quantum dot material.

23. (canceled)

24. (canceled)

25. The pixel of claim 3 wherein the container volume of the third sub-pixel is filled with a translucent material.
